(19) United States
(12) Patent Application Publication
(10) Pub. No.: US 2024/0203910 A1
(43) Pub. Date: Jun. 20, 2024

(54) DISPLAY DEVICE INCLUDING DISPLAY MODULE AND METHOD FOR MANUFACTURING SAME

(71) Applicant: SAMSUNG ELECTRONICS CO., LTD., Suwon-si (KR)

(72) Inventors: Tackmo LEE, Suwon-si (KR); Changkyu CHUNG, Suwon-si (KR); Gunwoo KIM, Suwon-si (KR); Soonmin HONG, Suwon-si (KR)

(73) Assignee: SAMSUNG ELECTRONICS CO., LTD., Suwon-si (KR)

(21) Appl. No.: 18/590,302

(22) Filed: Feb. 28, 2024

Related U.S. Application Data
(63) Continuation of application No. PCT/KR2022/014973, filed on Oct. 5, 2022.

(30) Foreign Application Priority Data
Nov. 24, 2021 (KR) 10-2021-0163461
Jan. 14, 2022 (KR) 10-2022-0005994

(51) Int. Cl. H01L 23/60; H01L 23/00; H01L 23/31; H01L 25/16

(52) U.S. Cl. CPC H01L 23/60; H01L 23/3192; H01L 24/29; H01L 24/32; H01L 25/167; H01L 24/33; H01L 2224/29028; H01L 2224/32145; H01L 2224/32175; H01L 2224/32225; H01L 2224/32245; H01L 2224/33181; H01L 2924/12041; H01L 2924/1426

(57) ABSTRACT

A display module includes a substrate including a mounting surface on which a plurality of inorganic light-emitting devices are mounted, a side surface, and a rear surface opposite to the mounting surface; a front cover covering the mounting surface and extending to an outer area from the mounting surface; a metal cover covering the rear surface and a first area of the side surface, the first area extending from the rear surface; and a side member positioned below the outer area from the mounting surface and adhered to a second area of the side surface, the second area extending from the mounting surface, and at least a portion of the metal cover. The metal cover includes a rear portion covering the rear surface, a side portion covering the first area of the side surface, and a bent portion bent between the rear portion and the side portion.

### CROSS-REFERENCE TO RELATED APPLICATIONS

This application is a continuation of International Application No. PCT/KR2022/014973, filed on Oct. 5, 2022, in the Korean Intellectual Property Receiving Office, which is based on and claims priority to Korean Patent Applications No. 10-2022-0005994, filed on Jan. 14, 2022 and No. 10-2021-0163461, filed on Nov. 24, 2021, in the Korean Intellectual Property Office, the disclosures of which are incorporated by reference herein in their entireties.

### BACKGROUND

### 1. Field

The present disclosure relates to a display device of displaying images by combining modules in which self-emissive inorganic light-emitting devices are mounted on substrates.

### 2. Description of Related Art

A display device is a kind of output device for visually displaying images and data information, such as characters, figures, etc.

Generally, as a display device, a liquid crystal panel requiring a backlight or an organic light-emitting diode (OLED) panel configured with a film of an organic compound that itself emits light in response to current has been widely used. However, the liquid crystal panel has a slow response time and high power consumption, and requires a backlight because itself cannot emit light. Accordingly, it is difficult to compactify the liquid crystal panel. Also, the OLED panel does not require a backlight and can achieve a small thickness because itself can emit light. However, the OLED panel is vulnerable to a burn-in phenomenon in which, when the same screen is displayed for a long time and then changes to another screen, a specific area of the previous screen remains as it is due to the short lifespan of the sub pixels. For these reasons, as a new panel that will substitute these, a micro light-emitting diode (referred to as a micro LED or a LED) panel that uses inorganic light-emitting devices mounted on substrates as pixels is being studied.

The micro light-emitting diode display panel (hereinafter, referred to as a micro LED panel), which is a flat display panel, is configured with a plurality of inorganic LEDs each having a size of 100 micrometers or less.

The micro LED panel does not cause the burn-in phenomenon of OLEDs as inorganic light-emitting devices that are self-emissive devices, while having excellent brightness, resolution, consumption power, and durability.

The micro LED display panel provides better contrast, response time, and energy efficiency than the LCD panel requiring the backlight. Micro LEDs which are inorganic light-emitting devices have higher brightness, higher light-emitting efficiency, and a longer lifespan than OLEDs although both the OLEDs and micro LEDs have high energy efficiency.

Also, display modules can be manufactured in unit of substrates by arranging LEDs in unit of pixels on circuit boards, and accordingly, micro LED display panels can be manufactured with various resolutions and screen sizes according to consumers' orders.

### SUMMARY

Provided is a display device and a manufacturing method thereof, and particularly, provides a technical feature of securing, in a display module suitable for enlargement and a display device including the same, reliability against Electrostatic Discharge (ESD) and rigidity against an external force with respect to a substrate of the display module.

Additional aspects will be set forth in part in the description which follows and, in part, will be apparent from the description, or may be learned by practice of the presented embodiments.

According to an aspect of an embodiment, a display module may include a substrate including a mounting surface on which a plurality of inorganic light-emitting devices are mounted, a side surface, and a rear surface opposite to the mounting surface; a front cover covering the mounting surface and extending to an outer area from the mounting surface; a metal cover covering the rear surface and a first area of the side surface, the first area extending from the rear surface; and a side member positioned below the outer area from the mounting surface and adhered to a second area of the side surface, the second area extending from the mounting surface, and at least a portion of the metal cover.

The metal cover may include a rear portion covering the rear surface, a side portion covering the first area of the side surface, and a bent portion bent between the rear portion and the side portion.

The rear portion, the side portion, and the bent portion may be integrated into one body.

The display module may further include a Thin Film Transistor (TFT) layer formed on the mounting surface, and an anisotropic conductive layer positioned on an upper surface of the TFT layer and configured to electrically connect the TFT layer to the plurality of inorganic light-emitting devices, where the anisotropic conductive layer extends to the outer area from the mounting surface.

The front cover may include a side end positioned in the outer area from the mounting surface, where the anisotropic conductive layer includes a side end positioned in the outer area from the mounting surface, and where the side end of the front cover and the side end of the anisotropic conductive layer are aligned in a direction which the mounting surface faces.

The side member may be adhered to at least a portion of a lower surface of the anisotropic conductive layer, the at least a portion of the lower surface corresponding to the outer area from the mounting surface.

The side member may include a side end positioned at an outer location from the side surface, where the side end of the side member, the side end of the front cover, and the side end of the anisotropic conductive layer are aligned in the direction which the mounting surface faces.

The side member may include a lower end forming a lower surface of the side member, where the lower end of the side member is positioned below the second area of the side surface in a direction which the mounting surface faces.

The substrate may further include a side wiring extending from the mounting surface to the rear surface and configured to electrically connect to the plurality of inorganic light-emitting devices, where the metal cover covers at least a portion of the side wiring extending on the side surface from the rear surface.

The side member may cover at least a portion of the side wiring extending on the side surface from the mounting surface.

The metal cover may include a conductivity greater than a conductivity of the front cover and a conductivity of the side member.

The side member may include a light absorbing material.

According to an aspect of an embodiment, a display device including a display module array in which a plurality of display modules are arranged horizontally in a matrix form of M*N, where each of the plurality of display modules may include: a substrate including a mounting surface on which a plurality of inorganic light-emitting devices are mounted, a side surface, and a rear surface being opposite to the mounting surface; a front cover covering the mounting surface and extending to an outer area from the mounting surface; a metal cover covering the rear surface and a first area of the side surface, the first area extending from the rear surface; and a side member positioned below the outer area from the mounting surface and adhered to a second area of the side surface, the second area extending from the mounting surface, and at least a portion of the metal cover.

The metal cover may include a rear portion covering the rear surface, a side portion covering the first area of the side surface, and a bent portion bent between the rear portion and the side portion.

The display device may further include a Thin Film Transistor (TFT) layer formed on the mounting surface, and an anisotropic conductive layer positioned on an upper surface of the TFT layer and configured to electrically connect the TFT layer to the plurality of inorganic light-emitting devices, where the anisotropic conductive layer extends to the outer area from the mounting surface.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 shows a display device according to an embodiment of the disclosure;

FIG. 2 is an exploded view showing main components of the display device of FIG. 1, according to an embodiment of the disclosure;

FIG. 3 is an enlarged cross-sectional view showing some components of a display module shown in FIG. 1, according to an embodiment of the disclosure;

FIG. 4 is a rear perspective view showing some components of a display module shown in FIG. 1, according to an embodiment of the disclosure;

FIG. 5 is a rear perspective view of a display module of the display device shown in FIG. 1, according to an embodiment of the disclosure;

FIG. 6 is a cross-sectional view showing some components of the display device of FIG. 1, taken in a second direction, according to an embodiment of the disclosure;

FIG. 7 is an enlarged cross-sectional view of some components shown in FIG. 6, according to an embodiment of the disclosure;

FIG. 8 is a cross-sectional view showing some components of the display device of FIG. 1, taken in a third direction, according to an embodiment of the disclosure;

FIG. 9 is an enlarged cross-sectional view of some components shown in FIG. 8, according to an embodiment of the disclosure;

FIG. 10 shows a process of manufacturing a display device, according to an embodiment of the disclosure;

FIG. 11 shows a process of manufacturing the display device after FIG. 10, according to an embodiment of the disclosure;

FIG. 12 shows a process of manufacturing the display device after FIG. 11, according to an embodiment of the disclosure;

FIG. 13 shows a process of manufacturing the display device after FIG. 12, according to an embodiment of the disclosure;

FIG. 14 shows a process of manufacturing the display device after FIG. 13, according to an embodiment of the disclosure;

FIG. 15 shows a process of manufacturing the display device after FIG. 14, according to an embodiment of the disclosure; and

FIG. 16 shows a process of manufacturing the display device after FIG. 15, according to an embodiment of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

An expression used in the singular encompasses the expression of the plural, unless it has a clearly different meaning in the context. In the drawings, for clear descriptions, the shapes or sizes of components are more or less exaggeratedly shown.

It will be understood that when the terms “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

Also, in this specification, the meaning of ‘identical’ may include similar in attribute or similar within a certain range. Also, the term ‘identical’ means ‘substantially identical’. The meaning of ‘substantially identical’ needs to be understood that a value falling within the margin of error in manufacturing or a value corresponding to a difference within a meaningless range with respect to a reference value is included in the range of ‘identical’.

Hereinafter, example embodiments of the disclosure will be described in detail with reference to the accompanying drawings.

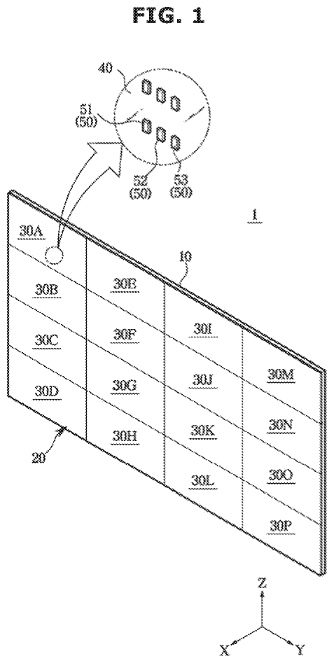

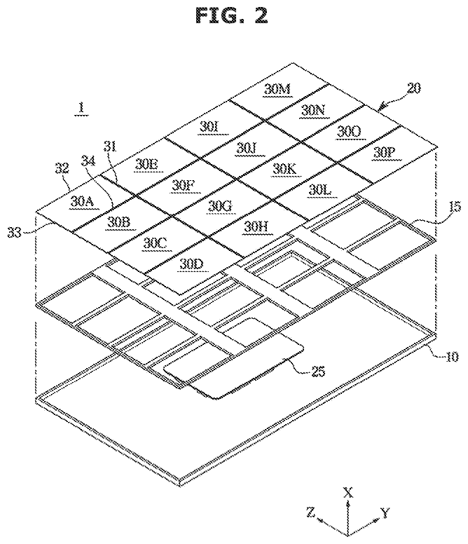

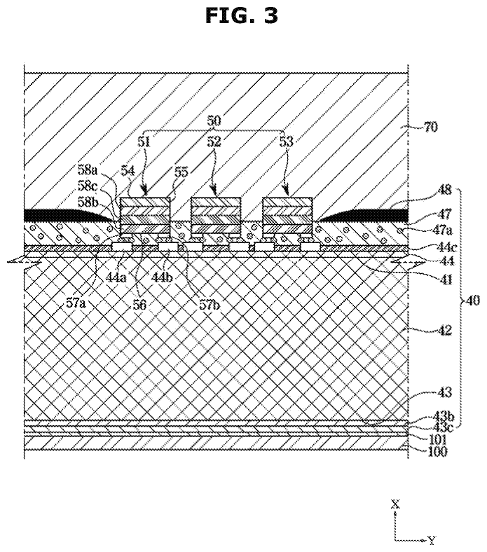

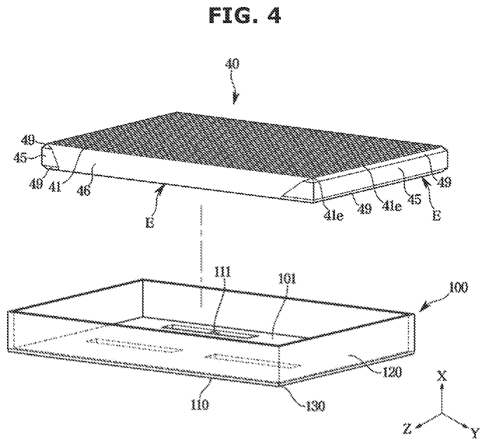

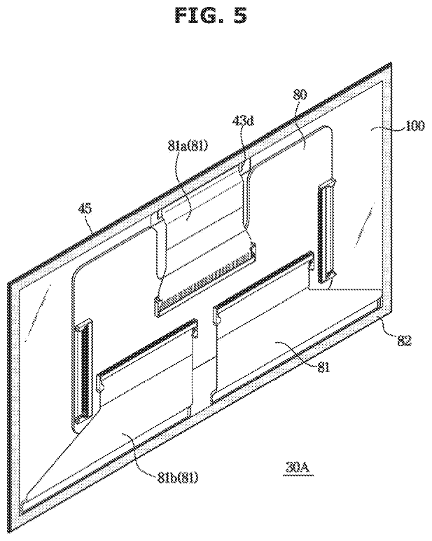

FIG. 1 shows a display device according to an embodiment of the disclosure, FIG. 2 is an exploded view showing main components of the display device of FIG. 1, FIG. 3 is an enlarged cross-sectional view showing some components of a display module shown in FIG. 1, FIG. 4 is a perspective view showing some components of a display module shown in FIG. 1, and FIG. 5 is a rear perspective view of a display module of the display device shown in FIG. 1.

Some components of a display device 1, including a plurality of inorganic light-emitting devices 50, shown in the drawings may be micro-scale components each having a size of several micrometers (μm) to hundreds of micrometers (μm), and for convenience of descriptions, some components (the plurality of inorganic light emitting devices 50, a black matrix 48, etc.) are exaggerated in scale.

The display device 1 may be a device for displaying information and data as characters, figures, graphs, images, etc., and the display device 1 may be a television (TV), a personal computer (PC), a mobile device, a digital signage, etc.

According to an embodiment of the disclosure, as shown in FIGS. 1 and 2, the display device 1 may include a display panel 20 for displaying an image, a power supply device for supplying power to the display panel 20, a main board 25 for controlling overall operations of the display panel 20, a frame 15 supporting the display panel 20, and a rear cover 10 covering a rear surface of the frame 15.

The display panel 20 may include a plurality of display modules 30A to 30P, a driving board for driving the individual display modules 30A to 30P, and a timing controller (TOCN) board for generating timing signals required for respectively controlling the display modules 30A to 30P.

The rear cover 10 may support the display panel 20. The rear cover 10 may be installed on a floor through a stand, or mounted on a wall through a hanger, etc.

The plurality of display modules 30A to 30P may be arranged in up, down, left, and right directions to be adjacent to each other. The plurality of display modules 30A to 30P may be arranged in a form of a M*N matrix. In the current embodiment, 16 display modules 30A to 30P may be arranged in a form of a 4*4 matrix. However, a number and arrangement of the plurality of display modules 30A to 30P are not limited.

The plurality of display modules 30A to 30P may be mounted on the frame 15. The plurality of display modules 30A to 30P may be mounted on the frame 15 by various known methods, such as a magnetic force generated by a magnet or a mechanical insert structure. A rear side of the frame 15 may be coupled with the rear cover 10, and the rear cover 10 may form a rear outer appearance of the display device 1.

The rear cover 10 may include a metal material. Accordingly, heat generated from the plurality of display modules 30A to 30P and the frame 15 may be easily transferred to the rear cover 10, which raises heat dissipation efficiency of the display device 1.

As such, the display device 1 according to an embodiment of the disclosure may implement a large screen by tiling the plurality of display modules 30A to 30P.

Each of the plurality of display modules 30A to 30P may be applied to a display device. That is, the display modules 30A to 30P may be, in unit of a piece, installed in and applied to a wearable device, a portable device, a handheld device, various electronic products, or electronic parts requiring a display. Also, the display modules 30A to 30P may be applied to a display device, such as a monitor for PC, a high-resolution TV, a signage, an electronic display, etc., by being assembled and arranged in a matrix type, as in the embodiment of the disclosure.

The plurality of display modules 30A to 30P may have the same configuration. Accordingly, the following description about a display module may be applied in the same way to all the other display modules.

Hereinafter, a first display module 30A of the plurality of display modules 30A to 30P will be described because the plurality of display modules 30A to 30P may have the same configuration.

That is, to avoid duplicate descriptions, as components of the plurality of display modules 30A to 30P, a display module 30, a substrate 40, and a front cover 70 will be representatively described.

Also, the first display module 30A of the plurality of display modules 30A to 30P and a second display module 30E being adjacent to the first display module 30A in a second direction Y or a third display module 30B being adjacent to the first display module 30A in a third direction Z will be described as necessary.

The first display module 30A of the plurality of display modules 30A to 30P may be formed, for example, in a quadrangle type. The first display module 30A may be formed in a rectangle type or a square type.

Accordingly, the first display module 30A may include edges 31, 32, 33, and 34 located in upper, lower, left, and right directions with respect to a first direction X which is a front direction.

As shown in FIG. 3, each of the plurality of display modules 30A to 30P may include the substrate 40, and the plurality of inorganic light-emitting devices 50 mounted on the substrate 40. The plurality of inorganic light-emitting devices 50 may be mounted on a mounting surface 41 of the substrate 40 toward the first direction X. In FIG. 3, for convenience of descriptions, a thickness in the first direction X of the substrate 400 is exaggerated.

The substrate 40 may be formed in a quadrangle type. As described above, because each of the plurality of display modules 30A to 30P is formed in a quadrangle type, the substrate 40 may also be formed in a quadrangle type correspondingly.

The substrate 40 may be formed in a quadrangle type or a square type.

Accordingly, in the example of the first display module 30A, the substrate 40 may include four edges E corresponding to the edges 31, 32, 33, and 34 of the first display module 30A, formed in the upper, lower, left, and right directions with respect to the first direction X which is the front direction (see FIG. 4).

The substrate 40 may include a substrate body 42, the mounting surface 41 forming one surface of the substrate body 42, a rear surface 43 forming another surface of the substrate body 42 and being opposite to the mounting surface 41, and a side surface 45 positioned between the mounting surface 41 and the rear surface 43.

The side surface 45 may form side ends of the substrate 40 in the second direction Y and the third direction Z that are orthogonal to the first direction X.

The substrate 40 may include a chamfer portion 49 formed between the mounting surface 41 and the side surface 45 and between the rear surface 43 and the side surface 45.

The chamfer portion 49 may prevent, upon an arrangement of the plurality of display modules 30A to 30P, each substrate from colliding with another one(s) and being damaged.

The edges E of the substrate 40 may include the side surface 45 and the chamfer portion 49.

The substrate 40 may include a thin film transistor (TFT) layer 44 formed on the substrate body 42 to drive the inorganic light-emitting devices 50. The substrate body 42 may include a glass substrate. That is, the substrate 40 may include a chip on glass (COG) type substrate. On the substrate 40, a first pad electrode 44a and a second pad electrode 44b may be formed to electrically connect the inorganic light-emitting devices 50 to the TFT layer 44.

TFTs configuring the TFT layer 44 are not limited to specific structures or types, and may be implemented as various embodiments. That is, TFTs of the TFT layer 44 according to an embodiment of the disclosure may be implemented as low temperature poly silicon (LTPS) TFTs, oxide TFTs, Si (poly silicon or a-silicon) TFTs, organic TFTs, or graphene TFTs.

Also, the TFT layer 44 may be replaced with a complementary metal-oxide semiconductor (CMOS) type, n-type MOSFET, or p-type MOSFET transistor, in a case in which the substrate body 42 of the substrate 40 is a silicon wafer.

The plurality of inorganic light-emitting devices 50 may be formed of an inorganic material, and each of the inorganic light-emitting devices 50 may have sizes of several micrometers (μm) to hundreds of micrometers (μm) in width, length, and height. A micro inorganic light-emitting device may have a shorter side length of 100 μm or less in width, length, and height. That is, the inorganic light-emitting devices 50 may be picked up from a sapphire or silicon wafer and then directly transferred onto the substrate 40. The plurality of inorganic light-emitting devices 50 may be picked up and conveyed through an electrostatic method using an electrostatic head or a stamp method using an elastic polymer material, such as PDMS or silicon, as a head.

The plurality of inorganic light-emitting devices 50 may include a light-emitting structure including an n-type semiconductor 58a, an active layer 58c, a p-type semiconductor 58b, a first contact electrode 57a, and a second contact electrode 57b.

Any one of the first contact electrode 57a and the second contact electrode 57b may be electrically connected to the n-type semiconductor 58a, and the other one may be electrically connected to the p-type semiconductor 58b.

The first contact electrode 57a and the second contact electrode 57b may be a flip chip type arranged horizontally toward the same direction (an opposite direction of a light-emitting direction).

Each inorganic light-emitting device 50 may include a light-emitting surface 54 positioned toward the first direction X upon being mounted on the mounting surface 41, a side surface 55, and a bottom surface 56 being opposite to the light-emitting surface 54, and the first contact electrode 57a and the second contact electrode 57b may be formed on the bottom surface 56.

That is, the contact electrodes 57a and 57b of the inorganic light-emitting device 50 may be opposite to the light-emitting surface 54, and accordingly, the contact electrodes 57a and 57b may be positioned in the opposite direction of the light-emitting direction.

The contact electrodes 57a and 57b may face the mounting surface 41, and be electrically connected to the TFT layer 44. Also, the light-emitting surface 54 through which light is irradiated may be positioned in an opposite direction of the direction in which the contact electrodes 57a and 57b are positioned.

Accordingly, light generated by the active layer 58c may be irradiated toward the first direction X through the light-emitting surface 54, without any interference by the first and second contact electrodes 57a and 57b.

That is, the first direction X may be defined as a direction in which the light-emitting surface 54 is positioned to irradiate light.

The first contact electrode 57a and the second contact electrode 57b may be electrically connected respectively to the first pad electrode 44a and the second pad electrode 44b formed on the mounting surface 41 of the substrate 40.

The inorganic light-emitting device 50 may be connected directly to the pad electrodes 44a and 44b through an anisotropic conductive layer 47 or a bonding material such as a solder.

On the substrate 40, the anisotropic conductive layer 47 may be formed to mediate an electrical connection between the contact electrodes 57a and 57b and the pad electrodes 44a and 44b. The anisotropic conductive layer 47 may be formed by applying an anisotropic conductive adhesive on a protective film, and have a structure in which conductive balls 47a are distributed in an adhesive resin. Each conductive ball 47a may be a conductive sphere surrounded by a thin insulating film, and as a result of a breaking of the insulating film by pressure, the conductive ball 47 may electrically connect a conductor to another one.

The anisotropic conductive layer 47 may include an anisotropic conductive film (ACF) being in a form of a film, and an anisotropic conductive paste (ACP) being in a form of a paste.

In an embodiment of the disclosure, the anisotropic conductive layer 47 may be provided as an anisotropic conductive film.

Accordingly, the insulating films of the conductive balls 47a may be broken by pressure applied to the anisotropic conductive layer 47 upon mounting of the plurality of inorganic light-emitting devices 50 on the substrate 40, and as a result, the contact electrodes 57a and 57b of the inorganic light-emitting devices 50 may be electrically connected to the pad electrodes 44a and 44b of the substrate 40.

The plurality of inorganic light-emitting devices 50 may be mounted on the substrate 40 through a solder, instead of the anisotropic conductive layer 47. By performing a reflow process after arranging the inorganic light-emitting devices 50 on the substrate 40, the inorganic light-emitting devices 50 may be adhered on the substrate 40.

The plurality of inorganic light-emitting devices 50 may include a red light-emitting device 51, a green light-emitting device 52, and a blue light-emitting device 53. The inorganic light-emitting devices 50 may be mounted in a group including the red light-emitting device 51, the green light-emitting device 52, and the blue light-emitting device 53 on the mounting surface 41 of the substrate 40. The red light-emitting device 51, the green light-emitting device 52, and the blue light-emitting device 53 may form a pixel. In this case, each of the red light-emitting device 51, the green light-emitting device 52, and the blue light-emitting device 53 may form a sub pixel.

The red light-emitting device 51, the green light-emitting device 52, and the blue light-emitting device 53 may be aligned with preset intervals, as in an embodiment of the disclosure. However, the red light-emitting device 51, the green light-emitting device 52, and the blue light-emitting device 53 may be arranged in another form such as a triangle.

The substrate 40 may include a light absorbing layer 44c for absorbing external light to improve contrast. The light absorbing layer 44c may be formed on the entirety of the mounting surface 41 of the substrate 40. The light absorbing layer 44c may be formed between the TFT layer 44 and the anisotropic conductive layer 47.

The plurality of display modules 30A to 30P may further include the black matrix 48 formed between the plurality of inorganic light-emitting devices 50.

The black matrix 48 may function to supplement the light absorbing layer 44c formed on the entire of the mounting surface 41 of the substrate 40. That is, the black matrix 48 may improve contrast of a screen by absorbing external light such that the substrate 40 is shown to be black.

The black matrix 48 may have a black color.

According to an embodiment, the black matrix 48 may be positioned between pixels each formed by the red light-emitting device 51, the green light-emitting device 52, and the blue light-emitting device 53. However, the black matrix 48 may be formed more finely to partition the light-emitting devices 51, 52, and 53 which are sub pixels.

The black matrix 48 may be formed in a shape of a lattice having a horizontal pattern and a vertical pattern to be positioned between the pixels.

The black matrix 48 may be formed by applying a light absorbing ink on the anisotropic conductive layer 47 through an ink-jet process and then hardening the light absorbing ink or by coating the anisotropic conductive layer 47 with a light absorbing film.

That is, the black matrix 48 may be formed in areas between the plurality of inorganic light-emitting devices 50, in which none of the plurality of inorganic light-emitting devices 50 is mounted, on the anisotropic conductive layer 47 formed on the entire of the mounting surface 41.

Each of the plurality of display modules 30A to 30P may include a front cover 70 positioned in the front direction X on the mounting surface 41 of the display modules 30A to 30P to cover the mounting surface 41.

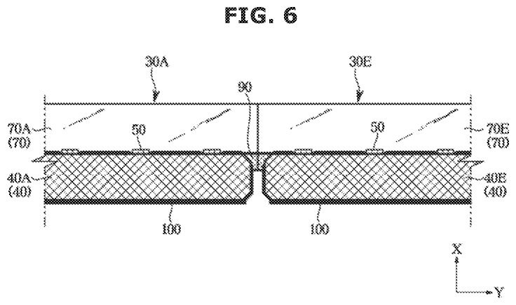

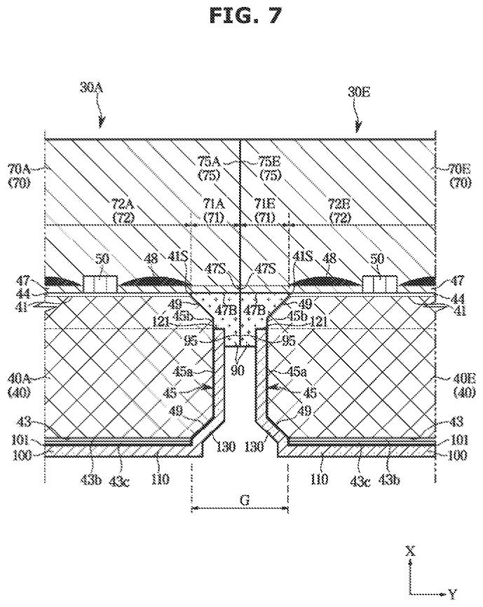

A plurality of front covers 70 may be respectively formed in the first direction X on the plurality of display modules 30A to 30P (see FIGS. 6 and 7).

The plurality of display modules 30A to 30P may be assembled with each other after the front covers 70 are respectively formed on the display modules 30A to 30P. That is, in an example of the first display module 30A and the second display module 30E among the plurality of display modules 30A to 30P, a first front cover 70A may be formed on the mounting surface 41 of the first display module 30A and a second front cover 70E may be formed on the mounting surface 41 of the second display module 30E.

The front cover 70 may cover the substrate 40 to protect the substrate 40 against an external force or outside water.

A plurality of layers of the front cover 70 may be provided as a functional film having optical performance. This will be described in detail, later.

Some of the plurality of layers of the front cover 70 may include a base layer formed of an optical clear resin (OCR). The base layer may support a plurality of other layers. The OCR may be in a very transparent state because the OCR has transmittance of 90% or more.

The OCR may improve visibility and image quality by raising transmittance through a low reflection property. That is, in a structure having an air gap, light loss occurs due to a refractive index difference between a film layer and an air layer. However, in a structure using an OCR, such a refractive index difference may be reduced to decrease light loss, resulting in an improvement of visibility and image quality.

That is, the OCR may improve image quality, in addition to protecting the substrate 40.

Some of the plurality of layers of the front cover 70 may include an adhesive layer for adhering the front cover 70 to the mounting surface 41 of the substrate 40.

Generally, the front cover 70 may have a height that is greater than or equal to a preset height in the first direction X which the mounting surface 41 or the light-emitting surface 54 faces.

The front cover 70 formed on the substrate 40 may have a height capable of sufficiently filling a gap that may be formed between the plurality of inorganic light-emitting devices 50 and the front cover 70.

Also, each of the plurality of display modules 30A to 30P may include a metal cover 100 that covers the rear surface 43 of the substrate 40, at least one portion of the side surface 45 of the substrate 40, and at least one portion of the side wiring 46. The metal cover 100 will be described in detail below.

Each of the plurality of display modules 30A to 30P may include a rear adhesive layer 101 positioned between the substrate 40 and the metal cover 100 to adhere the metal cover 100 to the substrate 40.

The rear adhesive layer 101 may be a double-sided tape, although not limited thereto. However, the rear adhesive layer 101 may be an adhesive layer, not a tape. That is, the rear adhesive layer 101 may be an embodiment of a medium for adhering the metal cover 100 to the substrate 40, and the rear adhesive layer 101 may be provided as one of various mediums, without being limited to a tape.

The plurality of inorganic light-emitting devices 50 may be electrically connected to a pixel driving wiring formed on the mounting surface 41, and an upper wiring layer extending through the side surface 45 of the substrate 40 and formed with a pixel driving wiring.

The upper wiring layer may be formed below the anisotropic conductive layer 47. The upper wiring layer may be electrically connected to the side wiring 46 formed on the side surface 45 of the substrate 40. The side wiring 46 may be provided in a form of a thin film.

Under an assumption that the second direction Y is a left-right direction of the display device 1, being orthogonal to the first direction X toward the front direction of the display device 1, and the third direction Z is an up-down direction of the display device 1, being orthogonal to the first direction X and the second direction Y, the side wiring 46 may extend to the rear surface 43 of the substrate 40 in the third direction Z along the chamfer portion 49 and the side surface 45 of the substrate 40 extending in the third direction Z, although not limited thereto.

However, the side wiring 46 may extend to the rear surface 43 of the substrate 40 in the second direction Y along the chamfer portion 49 and the side surface 45 of the substrate 40 extending in the second direction Y.

According to an embodiment of the disclosure, the side wiring 46 may extend along the edges E of the substrate 40, corresponding to the upper edge 32 and the lower edge 34 of the first display module 30A, although not limited thereto.

However, the side wiring 46 may extend along the edges E of the substrate 40, corresponding to at least two edges of the four edges 31, 32, 33, and 34 of the first display module 30A.

The upper wiring layer may be connected to the side wiring 46 by an upper connecting pad formed on the edges E of the substrate 40.

The side wiring 46 may extend along the side surface 45 of the substrate 40 and be connected to a rear wiring layer 43b formed on the rear surface 43.

An insulating layer 43c may be formed on the rear wiring layer 43b in a direction which the rear surface 43 of the substrate 40 faces, to cover the rear wiring layer 43b.

That is, the plurality of inorganic light-emitting devices 50 may be electrically connected to the upper wiring layer, the side wiring 46, and the rear wiring layer 43b, sequentially.

Also, as shown in FIG. 5, the display module 30A may include a driving circuit board 80 for electrically controlling the plurality of inorganic light-emitting devices 50 mounted on the mounting surface 41. The driving circuit board 80 may be a printed circuit board. The driving circuit board 80 may be positioned on the rear surface 43 of the substrate 40 in the first direction X. The driving circuit board 80 may be positioned on the metal cover 100 adhered on the rear surface 43 of the substrate 40.

The display module 30A may include a flexible film 81 connecting the driving circuit board 80 to the rear wiring layer 43b to electrically connect the driving circuit board 80 to the plurality of inorganic light-emitting devices 50.

One end of the flexible film 81 may be connected to a rear connecting pad 43d positioned on the rear surface 43 of the substrate 40 and electrically connected to the plurality of inorganic light-emitting devices 50.

The rear connecting pad 43d may be electrically connected to the rear wiring layer 43b. Accordingly, the rear connecting pad 43d may electrically connect the rear wiring layer 43b to the flexible film 81.

Because the flexible film 81 is electrically connected to the rear connecting pad 43d, the flexible film 81 may transfer power and an electrical signal from the driving circuit board 80 to the plurality of inorganic light-emitting devices 50.

The flexible film 81 may be a flexible flat cable (FFC) or a chip on film (COF).

The flexible film 81 may include a first flexible film 81a and a second flexible film 81b respectively positioned in upper and lower directions with respect to the first direction X which is the front direction, although not limited thereto.

The first flexible film 81a and the second flexible film 81b may be positioned in left and right directions with respect to the first direction X, or in at least two directions of the upper, lower, left, and right directions.

A plurality of second flexible films 81b may be provided, although not limited thereto. However, a single second flexible film 81b may be provided, and a plurality of first flexible films 81a may also be provided.

The first flexible film 81a may transfer a data signal from the driving circuit board 80 to the substrate 40. The first flexible film 81a may be a COF, although not limited thereto.

The second flexible film 81b may transfer power from the driving circuit board 80 to the substrate 40. The second flexible film 81b may be a FFC, although not limited thereto.

However, the first flexible film 81a and the second flexible film 81b may be a COF and a FFC, respectively.

The driving circuit board 80 may be electrically connected to the main board 25 (see FIG. 2). The main board 25 may be positioned behind the frame 15, and the main board 25 may be connected to the driving circuit board 80 through a cable behind the frame 15.

On a rear surface of the metal cover 100, a fixing member 82 for adhering the display modules 30A to 30P to the frame 15 may be positioned. The fixing member 82 may be a double-sided tape. The metal cover 100 forming a rear side of each of the display modules 30A to 30P may be adhered directly to the frame 15 by the fixing member 82 such that the display modules 30A to 30P are supported by the frame 15.

As described above, the metal cover 100 may be in contact with the substrate 40. As shown in FIG. 4, the metal cover 100 may cover the rear surface 43 of the substrate 40, at least one portion of the side surface 45 of the substrate 40, and at least one portion of the side wiring 46.

FIG. 4 shows the substrate 40 from which some components such as the anisotropic conductive layer 47 are omitted for convenience of descriptions. Also, the side wiring 46 may include a coating member 46a for protecting the side wiring 46 from the outside, and the coating member 46a is not shown for convenience of description.

The metal cover 100 may be formed of a metal material having high heat conductivity. For example, the metal cover 100 may be in a shape of a sheet formed of a copper material.

Heat generated from the TFT layer 44 and the plurality of inorganic light-emitting devices 50 mounted on the substrate 40 may be transferred to the metal cover 100 through the rear adhesive layer 101 along the substrate 40.

Accordingly, heat generated from the substrate 40 may be easily transferred to the metal cover 100 to prevent temperature of the substrate 40 from rising to preset temperature or more.

The plurality of display modules 30A to 30P may be arranged at various locations in a M×N matrix form. The individual display modules 30A to 30P may be movable independently. In this case, each of the display modules 30A to 30P may include the metal cover 100 to maintain a certain level of heat dissipation performance regardless of the locations of the display modules 30A to 30P.

The plurality of display modules 30A to 30P may be arranged in various M×N matrix forms to implement various screen sizes of the display device 1. Accordingly, radiating heat from the individual display modules 30A to 30P by including the metal cover 100 in each of the display modules 30A to 30P as in an embodiment of the disclosure may improve total heat-radiating performance of the display device 1 more than radiating heat through a single metal plate provided for temporary heat radiation.

In a case in which a single metal plate is positioned inside the display device 1, the metal plate may not exist at a location corresponding to a location of some display modules in a front-rear direction while existing at a location where no display module is positioned, resulting in deterioration of heat dissipation efficiency of the display device 1.

That is, all of the individual display modules 30A to 30P may radiate heat through the metal cover 100 positioned in each of the display modules 30A to 30P regardless of the locations, which leads to an improvement of total heat dissipation performance of the display device 1.

The metal cover 100 may include a rear portion 110 corresponding to the rear surface 43 of the substrate 40 and covering the rear surface 43, a side portion 120 covering at least one portion of the side surface 45 of the substrate 40 and the side wiring 46, and a bent portion 130 bent between the rear portion 110 and the side portion 120.

The metal cover 100 may be prepared in a shape of a sheet, and in a subsequent process, the metal cover 100 may be bent at the bent portion 130 to form a box shape of which an upper side opens.

The rear portion 110 may be provided with a size corresponding to the rear surface 43 of the substrate 40. The rear portion 110 may protect a rear surface wiring layer 43b formed on the rear surface 43 from an external force.

The rear portion 110 may include a through hole 111 through which the flexible film 81 electrically connected to the rear wiring layer 43b penetrates the rear portion 110 to connect to the driving circuit 80.

The bent portion 130 may be bent substantially in a vertical direction from the rear portion 110. The bent portion 130 may cover the chamfer portion 49 positioned between the rear surface 43 and the side surface 45.

The bent portion 130 may be bent, as described above, in the vertical direction to be orthogonal to the rear portion 110, although not limited thereto. However, the bent portion 130 may be bent in an oblique direction corresponding to the chamfer portion 49 with respect to the rear surface 43 to cover the chamfer portion 49 and then bent in a direction that is orthogonal to the rear portion 110.

The side portion 120 may cover at least one portion of the side surface 45 positioned at each of the four edges E of the substrate 40 that is in a shape of a rectangle.

As described above, because the side wiring 46 is positioned on the side surfaces 45 of two edges E extending in the upper and lower directions of the substrate 40 along the third direction Z, the side portion 120 may cover at least one portion of the side wiring 46 in the third direction Z of the substrate 40 and at least one portion of the side surface 45 in the second direction Y of the substrate 40.

The metal cover 100 may be adhered to the rear surface 43 of the substrate 40 and at least one portion of the side surface 45 or at least one portion of the side wiring 46, by the rear adhesive layer 101.

The rear adhesive layer 101 may have a size corresponding to the metal cover 100. That is, an area of the rear adhesive layer 101 may correspond to an area of the metal cover 100. The metal cover 100 may be bent from a substantially rectangular sheet shape, and the rear adhesive layer 101 may also be bent from a rectangular shape correspondingly.

Because the metal cover 100 and the rear adhesive layer 101 are capable of being easily manufactured as one combined component, total manufacturing efficiency of the display device 1 may increase.

That is, before a plate is cut into unit pieces to form the metal cover 100, the rear adhesive layer 101 may be adhered on the plate and then the rear adhesive layer 101 and the plate may be cut together into unit pieces, thereby reducing a number of processes.

Heat generated from the substrate 40 may be transferred to the metal cover 100 through the rear adhesive layer 101. Accordingly, the rear adhesive layer 101 may adhere the metal cover 100 on the substrate 40, while transferring heat generated from the substrate 40 to the metal cover 100.

Accordingly, the rear adhesive layer 101 may include a material having high heat dissipation performance.

The rear adhesive layer 101 may include a material having an adhesive property to adhere the substrate 40 to the metal cover 100.

Additionally, the rear adhesive layer 101 may include a material having high heat dissipation performance rather than materials having an adhesive property. Accordingly, the rear adhesive layer 101 may efficiently transfer heat between the substrate 40 and the metal cover 100.

Also, the material having the adhesive property, included in the rear adhesive layer 101, may be a material having higher heat dissipation performance than adhesive materials constituting existing adhesives.

The material having the higher heat dissipation performance may be a material capable of effectively transferring heat because the material has high heat conductivity, high heat transfer performance, and low specific heat.

Flexibility of the rear adhesive layer 101 may be greater than flexibility of the substrate 40 and the metal cover 100. Accordingly, the rear adhesive layer 101 may be formed of a material having an adhesive property, heat dissipation, and high flexibility.

The rear adhesive layer 101 may be, for example, a baseless double-sided tape. In this case, the rear adhesive layer 101 may be formed as a single layer of which one side is adhered on the substrate 40 and the other side is adhered on the metal cover 100, without having any base supporting the one side and the other side.

Because the rear adhesive layer 101 includes no base, the rear adhesive layer 101 may include no material interfering with heat conduction, and accordingly, heat dissipation performance may increase. However, the rear adhesive layer 101 is not limited to a baseless double-sided tape, and may be a heat dissipation tape having higher heat dissipation performance than existing double-sided tapes.

The rear adhesive layer 101 may be formed of a material having high flexibility to absorb an external force transferred from the substrate 40 and the metal cover 100. Flexibility of the rear adhesive layer 101 may be higher than flexibility of the substrate 40 and the metal cover 100.

Accordingly, upon a transfer of an external force generated by changed sizes of the substrate 40 and the metal cover 100, by heat transferred to the substrate 40 and the metal cover 100 to the rear adhesive layer 101, the rear adhesive layer 101 may be deformed to prevent the external force from being transferred to the other components.

Hereinafter, the front cover 70, the side member 90, and the metal cover 100 will be described in detail.

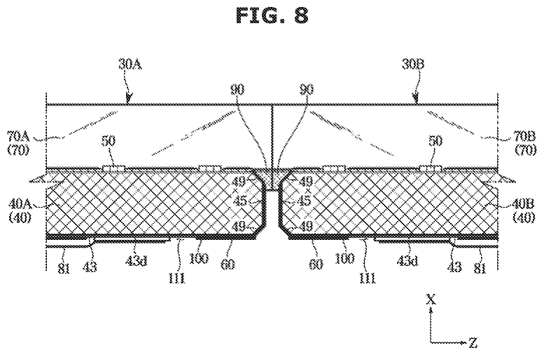

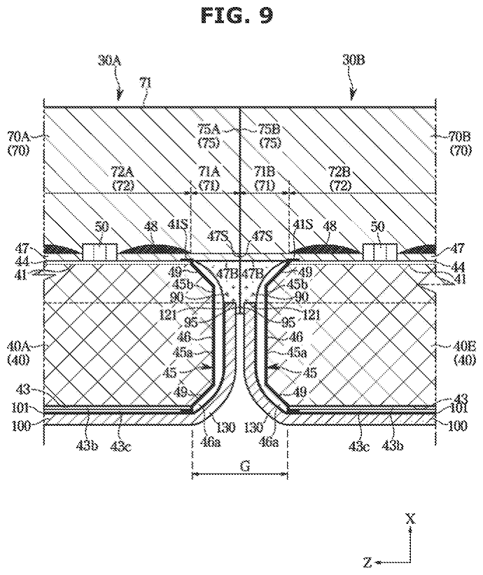

FIG. 6 is a cross-sectional view showing some components of the display device of FIG. 1, taken in a second direction, FIG. 7 is an enlarged cross-sectional view of some components shown in FIG. 6, FIG. 8 is a cross-sectional view showing some components of the display device of FIG. 1, taken in a third direction, and FIG. 9 is an enlarged cross-sectional view of some components shown in FIG. 8.

The front cover 70 may protect the substrate 40 against an external force and reduce visibility of seams formed by the gaps G between the plurality of display modules 30A to 30P while improving color deviation between the plurality of display modules 30A to 30P.

Each of the plurality of display modules 30A to 30P may include the side member 90 positioned in a gap G formed between the plurality of display modules 30A to 30P upon an arrangement of the plurality of display modules 30A to 30P.

To absorb light reflected in the gaps G between the plurality of display modules 30A to 30P, the front covers 70 of the respective display modules 30A to 30P may extend to more outer locations than the substrates 40 of the plurality of display modules 30A to 30P. Side ends 75 of each front cover 70 may extend to an outer location from the mounting surface 41.

The front cover 70 may extend to a more outer location than an edge (or a side end) 41e of the mounting surface 41 of the substrate 40 in the second direction Y and the third direction Z (see FIG. 4).

The gaps between the display modules 30A to 30P may be made between side surfaces 45 of the substrates 40 of the display modules 30A to 30P. However, a gap G in an embodiment of the disclosure means a non-display area that may be made between the display modules 30A to 30P, and accordingly, the gap G formed between the plurality of display modules 30A to 30P may be understood as a space formed between an edge 41S of a mounting surface 41 of a substrate 40 of one of the display modules 30A to 30P and an edge 41S of a mounting surface 41 of a substrate 40 of a neighboring display module 30A to 30P.

Accordingly, the gap G formed between the plurality of display modules 30A to 30P means a space formed between an edge 41S of a mounting surface 41 of one of the display modules 30A to 30P and an edge 41S of a mounting surface 41 of a neighboring display module 30A to 30P in the second direction Y or the third direction Z.

The front covers 70 extending from the respective display modules 30A to 30P may be positioned at the gaps G between the plurality of display modules 30A to 30P to absorb light irradiated into the gaps G or light reflected from the gaps G, thereby minimizing recognition of seams.

Also, light irradiated into the gaps G may be absorbed in the side member 90 of the plurality of display modules 30A to 30P, positioned between the gaps G, thereby minimizing recognition of seams, which will be described below.

As shown in FIGS. 6 and 7, the front cover 70 may extend to an outer location from the substrate 40 in the second direction Y. The front cover 70 may extend to a more outer location than the side surface 45 and the chamfer portion 49 in the second direction Y.

According to an embodiment of the disclosure, while an edge of the substrate 40, corresponding to a right edge 31 of the first display module 30A is described, the front cover 70 may extend to a more outer location than the four edges E of the substrate 40 in the second direction Y or the third direction Z.

That is, the side ends 75 of the front cover 70, which correspond to edges of the front cover 70, may extend to an outer area from the substrate 40, that is, to a more outer area from the mounting surface 41 than the four edges E of the substrate 40 in the second direction Y or the third direction Z.

The front cover 70 may include a plurality of layers having different optical properties, although not shown in the drawings. The plurality of layers may be provided in a structure in which the layers are stacked in the first direction X.

The plurality of layers may constitute the front cover 70 by being combined with each other in the first direction X.

One of the plurality of layers may be an anti-glare layer, although not limited thereto. However, one of the plurality of layers may be an anti-reflective layer or a combined layer of an anti-glare layer and an anti-reflective layer.

Another one of the plurality of layers may be a light transmittance adjustable layer, although not limited thereto. However, the layer may be a layer having another physical property or including another material, or a layer having another function. For example, the layer may be a circularly polarized layer.

Also, a single layer, instead of the plurality of layers, may be provided. The single layer may be a layer capable of implementing all functions of the plurality of layers.

As described above, the front cover 70 may include an adhesive layer. The adhesive layer may be positioned at a hindmost location of the plurality of layers in the first direction X and adhered on the mounting surface 41. The adhesive layer may have a height that is greater than or equal to a preset height in the first direction X which the mounting surface 41 or the light-emitting surface 54 faces.

The reason may be to cause the adhesive layer adhered on the substrate 40 to sufficiently fill a gap that may be formed between the adhesive layer and the plurality of inorganic light-emitting devices 50.

However, the adhesive layer is not limited to the embodiment of the disclosure, and the adhesive layer may be positioned as a separate component from the front cover 70 between the front cover 70 and the mounting surface 41 to adhere the front cover 70 with the mounting surface 41.

Accordingly, because the front cover 70 is adhered with the mounting surface 41 while being in close contact with the mounting surface 41 and protects components mounted on the mounting surface 41, the display module 30 may adhere the front cover 70 directly to the substrate 40 without any additional molding component formed between the front cover 70 and the substrate 40.

The front cover 70 may diffuse and reflect light received from the outside to prevent the light from being specularly reflected to dazzle a user's eyes.

By diffusing and reflecting light received from the outside, a glaring phenomenon may be reduced, and accordingly, contrast of a screen displayed on the display panel 20 may be improved.

Also, the front cover 70 may reduce transmittance of incident external light or external light reflected from the substrate 40 and the gap G.

The front cover 70 according to an embodiment of the disclosure may include a material capable of reducing transmittance of light, to absorb at least one part of light transmitted toward the substrate 40 or light reflected from the substrate 40 and then traveling toward the first direction X.

While a plurality of substrates are manufactured, some of the substrates may have different colors due to a process error in the manufacturing process. Accordingly, substrates having different unique colors may be tiled to constitute a single display panel.

As described above, the front cover 70 according to an embodiment of the disclosure may absorb at least one part of light reflected from the substrate 40 and transmitted to the outside, thereby raising a sense of unity of a screen displayed on the display panel 20.

That is, the front cover 70 may reduce color deviation generated during processes of the plurality of display modules 30A to 30P by lowering transmittance with respect to external light.

The front cover 70 may prevent external light entered the display panel 20 from the outside from being transmitted to the substrate 40, and additionally absorb a part of light entered the display panel 20 from the outside or a part of external light reflected from the substrate 40 and then transmitted to the outside of the display panel 20, thereby improving contrast of a screen that is displayed on the display panel 20. Such different optical actions may be respectively implemented by the plurality of layers described above.

That is, the front cover 70 may be positioned in front of the substrate 40 in the first direction X to improve contrast that may be deteriorated by external light in a screen displayed on the display panel 20.

As described above, in the display module 30 according to an embodiment of the disclosure, the front cover 70 may extend to the outer location from the substrate 40 in the second direction Y.

Accordingly, a part of light that has entered the gap G formed between the plurality of display modules 30A to 30P may be blocked by at least one portion of the front cover 70 positioned in the gap G, and at least a part of external light that has entered the gap G or reflected in the gap G may be absorbed by the front cover 70 positioned in the gap G and thus be not transmitted to the outside. Accordingly, visibility of a seam that is formed in the gap G may deteriorate, and due to the deterioration of the visibility of the seam, a sense of unity of a screen that is displayed on the display panel 20 may be improved.

The side end 75 of the front cover 70 in the second direction Y may be positioned at a more outer location than the edge 41S of the mounting surface 41 in the second direction Y, or in the gap G.

Accordingly, the front cover 70 may include a first area 71 positioned at the more outer location than the edge 41S of the mounting surface 41 in the second direction Y or in the gap G, and a second area 72 positioned above the mounting surface 41.

The first area 71 and the second area 72 of the front cover 70 may be partitioned by the gap G in the second direction Y.

Because the first area 71 of the front cover 70 is positioned in the gap G, external light irradiated toward the gap G may be blocked by the first area 71 of the front cover 70 or light reflected in the gap G may be prevented from being irradiated to the outside. Accordingly, visibility of a seam which is a boundary between the plurality of display modules 30A to 30P and which may be formed by the gap G may be reduced, resulting in an improvement of a sense of unity of the display panel 20.

Because the front cover 70 extends to the more outer location than the four edges 41S of the mounting surface 41 of the substrate 40, as described above, visibility of seams that may be formed at the edges of the plurality of display modules 30A to 30P may be reduced.

In the example of the first display module 30A and the second display module 30E, a first area 71A of a first front cover 70A extending from the first display module 30A may be positioned in a gap G formed between the first display module 30A and the second display module 30E.

In the gap G, neighboring side ends 75A and 75E of the front covers 70A and 70E of the first and second display modules 30A and 30E may be positioned.

Also, in the gap G, the side surfaces 45 and chamfer portions 49 of the first and second display modules 30A and 30E may be positioned.

A second area 72A of the first front cover 70A may be positioned above the mounting surface 41 of the first display module 30A.

A first area 71E of the second cover 70E extending from the second display module 30E may be positioned in the gap G formed between the first display module 30A and the second display module 30E, and a second area 72E of the second front cover 70E may be positioned above the mounting surface 41 of the second display module 30E.

That is, in the gap G formed between the first display module 30A and the second display module 30E, the first areas 71A and 71E of the first and second front covers 70A and 70E may be positioned side by side in the second direction Y.

Lengths in the second direction Y of the first areas 71A and 71E of the first and second front covers 70A and 70E may be substantially smaller than or equal to half of a length of the gap G. The length of each of the first area 71A of the first front cover 70A and the first area 71E of the second front cover 70E may be ½ the length of the gap G.

Accordingly, a sum of the lengths of the first areas 71A and 71E of the first and second front covers 70A and 70E arranged side by side in the second direction Y may substantially correspond to or be smaller than the length of the gap G. A sum of the lengths of the first areas 71A and 71E of the first and second front covers 70A and 70E may be equal to the length of the gap G.

Accordingly, the side end 75A of the first front cover 70A, which is adjacent to the second front cover 70E, may be in contact with the side end 75E of the second front cover 70E, which is adjacent to the first front cover 70A, while facing the side end 75E of the second front cover 70E.

Accordingly, the first display module 30A and the second display module 30E may be tiled without any space between the first area 71A of the first front cover 70A and the first area 71E of the second cover 70E.

Additionally, a side end 47S of the anisotropic conductive layer 47 of the display module 30 may be aligned with the side end 75 of the front cover 70 in the first direction X. The reason may be because the anisotropic conductive layer 47 and the front cover 70 of the display module 30 are cut and processed simultaneously during a process, which will be described below.

Accordingly, a side end 47S of an anisotropic conductive layer 47 of the first display module 30A, which is adjacent to the second display module 30E, may be in contact with a side end 47S of an anisotropic conductive layer 47 of the second display module 30E, which is adjacent to the first display module 30A, while facing the side end 47S of the anisotropic conductive layer 47 of the second display module 30E.

As described above, the first area 71A of the first front cover 70A and the first area 71E of the second front cover 70E may be positioned above the gap G between the first display module 30A and the second display module 30E.

External light that has entered the display panel 20 may be diffused and reflected to the outside of the display panel 20 by being transmitted through the first areas 71A and 71E of the first and second front covers 70A and 70E, or a part of the external light may be absorbed in the first areas 71A and 71E. Accordingly, an amount of light arrived at the gap G may be reduced, and visibility of a boundary between the first display module 30A and the second display module 30E by the gap G may be reduced.

Also, light reflected in the gap G and then traveling to the outside of the display panel 20 may be diffused and reflected to the outside of the display panel 20 while being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, which reduces visibility of the boundary between the first display module 30A and the second display module 30E, caused by the gap G.

That is, by reducing an amount of external light entering the gap G formed between the plurality of display modules 30A to 30P while absorbing at least one part of the external light reflected in the gap G, a sense of unity of a screen displayed on the display panel 20 may be improved.

Additionally, although a substrate 40A of the first display module 30A and a substrate 40E of the second display module 30E have different colors, at least one part of external light reflected from the substrates 40A and 40E may be absorbed in the first and second front covers 70A and 70E. Accordingly, unique colors of the substrates 40A and 40E may not be recognized from the outside, which improves a sense of unity of a screen displayed on the display panel 20.

As described above, the metal cover 100 may cover the rear surface 43 of the substrate 40 and at least one portion of the side surface 45 in the second direction Y. The metal cover 100 may cover at least one portion of the side wiring 46 in the third direction Z. This will be described below.

The side portion 120 of the metal cover 100 may extend to a preset length from the rear portion 110 in the first direction X. Accordingly, a front end of the side portion 120 may be positioned on the side surface 45 in the first direction X.

The side surface 45 may include a first area 45a covered by the side portion 120 and extending in the first direction X from the rear surface 43, and a second area 45b positioned in front of the first area 45a in the first direction X and extending from the mounting surface 41.

The first area 45a of the side surface 45 may be covered by the metal cover 100 to be protected from an external force.

The first area 45a of the side surface 45 may be adhered with the rear adhesive layer 101 of the metal cover 100.

The rear surface 43 and the rear wiring layer 43b formed on the rear surface 43, as well as the first area 45a of the side surface 45, may also be protected from an external force by the metal cover 100.

The metal cover 100 may protect the substrate 40 from an external force, and prevent components mounted on the substrate 40 from being damaged by an electrostatic discharge, which will be described below.

The display module 30A may include the side member 90 positioned below the front cover 70 in the direction which the mounting surface 41 faces, and provided on the side surface 45 of the substrate 40.

The side member 90 may be positioned in a space defined by a lower surface 47B of the anisotropic conductive layer 47 corresponding to a lower surface of the first area 71 of the front cover 70 in the first direction X and the side surface 45 of the substrate 40 in the second direction Y.

The side member 90 may be adhered to the lower surface 47B of the anisotropic conductive layer 47 positioned on the first area 71, at least one portion of the side surface 45, and at least one portion of the metal cover 100.

The side member 90 may be adhered to the lower surface 47B of the anisotropic conductive layer 47 positioned on the first area 71, the second area 45b of the side surface 45, the chamfer portion 49 positioned between the mounting surface 41 and the second area 45b of the side surface 45, and at least one portion of the side portion 120 including an upper end 121 of the side portion 120 and extending from the upper end 121 of the side portion 120.

As described above, the first area 45a of the side surface 45 may be protected from the outside by the metal cover 100, and the second area 45b of the side surface 45 may be protected from the outside by the side member 90.

Because the side member 90 surrounds the chamfer portion 49 formed between the mounting surface 41 and the side surface 45, the lower surface 47B of the anisotropic conductive layer 47 positioned at the first area 71, the second area 45b of the side surface 45, and at least one portion of the metal cover 100, the side member 90 may fill all spaces that may be made between the substrate 40 and the front cover 70.

Accordingly, the side member 90 and the metal cover 100 may seal the side surface 45 from the outside, and prevent foreign materials or water from entering the space formed by the substrate 40, the front cover 70, and the anisotropic conductive layer 47.

The side member 90 may support the lower surface 47B of the anisotropic conductive layer 47 positioned at the first area 71, the chamfer portions 49 of the substrate 40, and the side surface 45 of the substrate 40.

As described above, while the front cover 70 is adhered to the substrate 40, adhesion between the front cover 70 and the substrate 40 may be enhanced by the side member 90. Accordingly, the side member 90 may prevent the front cover 70 from departing from the substrate 40.

That is, reliability of the display module 30A may rise by the side member 90.

As described above, the side surface 45 of the substrate 40 may correspond to the four edges 41S of the mounting surface 41, and the first area 71 of the front cover 70 may extend to more outer locations than the four edges 41S of the mounting surface 41 in the second direction Y and the third direction Z in which the mounting surface 41 extends.

The side member 90 may surround the second area 45b of the side surface 45 corresponding to each of the four edges 41S of the mounting surface 41 and at least one portion of the side portion 120, along the four edges 41S of the mounting surface 41.

That is, the side member 90 may seal all edges of a portion at which the substrate 40 is adhered with the front cover 70.

The side member 90 may cover the lower surface of the first area 71, the lower surface 47B of the anisotropic conductive layer 47 corresponding to the first area 71, the second area 45b of the side surface 45, and a portion of the side portion 120 extending from the front end 121 of the side portion 120, in all directions that are orthogonal to the first direction X.

Accordingly, adhesion between the front cover 70, the substrate 40, and the metal cover 100 may be improved, and the front cover 70 and the side surface 45 of the substrate 40 may be protected from an external force.

Also, outside water or a foreign material may be prevented from entering between the substrate 40 and the front cover 70, as described above. In addition, upon formation of a gap between the substrate 40 and the front cover 70 due to degradation of adhesion, outside water or a foreign material may be prevented from entering the gap.

The side member 90 may surround all the four edges E of the substrate 40 along the side surface 45 of the substrate 40 to seal between the substrate 40, the front cover 70, and the metal cover 100.

Also, current may flow to a plurality of electronic components mounted on the substrate 40 by an electrostatic discharge which may be generated on the display modules 30A to 30P to damage the electronic components, and the side member 90 may seal the substrate 40 from the outside and thus block charges generated by the electrostatic discharge from entering the substrate 40, to prevent the electronic components from being damaged.

That is, because the substrate 40 is sealed by the front cover 70 and the side member 90, charges generated by an electrostatic discharge may be prevented from passing through the front cover 70 and the side member 90 and thus flowing to the substrate 40, and charges flowing on the front cover 70 and the side member 90 may be guided to the metal cover 100 being in contact with the side member 90, thereby providing a path for current generated by the electrostatic discharge. Because the metal cover 100 is made of a copper material having high conductivity, as described above, current may flow to the metal cover 100. Accordingly, electrostatic discharge (ESD) resistant pressure of the electronic components mounted on the substrate 40 may be improved.

As described above, the side member 90 may be positioned below the front cover 70 in the direction which the mounting surface 41 faces. That is, the side member 90 may not be positioned above the lower surface of the front cover 70 in the first direction X.

A front end of the side member 90 in the first direction X may be in contact with the lower surface 47B of the anisotropic conductive layer 47 at the first area 71, and may not be positioned before the lower surface of the first area 71 in the first direction X.

The reason may be not to locate the side member 90 on a traveling path of light emitted from the plurality of inorganic light-emitting devices 50.

In a case in which at least one portion of the side member 90 is positioned before the lower surface 76 in the first direction X or before the front cover 70 in the first direction X, the at least one portion of the side member 90 may be positioned on a traveling path of light traveling forward through the front cover 70.

That is, the side member 90 may absorb or diffuse and reflect a part of traveling light to distort an area of an image displayed on the display panel 20.

However, because the side member 90 according to an embodiment of the disclosure is positioned behind the front cover 70 in the first direction X, the side member 90 may not limit traveling of light emitted from the plurality of light-emitting devices 50, thereby improving image quality of the display panel 20.

The side end 75 of the front cover 70 in the second direction Y and a side end 95 of the side member 90 in the second direction Y may be aligned in the first direction X. Also, the side end 75 of the front cover 70, the side end 47S of the anisotropic conductive layer 47, and the side end 95 of the side member 90 may be aligned in the first direction X.

The reason may be because the front cover 70, the anisotropic conductive layer 47, and the side member 90 are cut simultaneously in a process of manufacturing the display module 30A.

That is, a space that may be formed between the plurality of display modules 30A to 30P upon an arrangement of the plurality of display modules 30A to 30P may be minimized, and visibility of a seam, which is caused by the space between the plurality of display modules 30A to 30P, may be minimized.

The side member 90 may include a light absorbing material. For example, the side member 90 may be formed of an opaque or translucent material.

Also, the side member 90 may include a photosensitive material. For example, the side member 90 may be formed of a photosensitive optical clear resin (OCR). The photosensitive material may change physical properties to show a dark color by receiving external light such as ultraviolet (UV) light having a wavelength that is different from a wavelength of visible light.

Accordingly, by irradiating UV light to the side member 90 during a manufacturing process to color the side member 90 with a dark color, the side member 90 may be provided as a light absorbing member.

The side member 90 may have a dark color. The side member 90 may have a darker color than the front cover 70.

The side member 90 may have a similar color to that of the black matrix 48.

Accordingly, light entered into the side member 90 may be absorbed in the side member 90 without being reflected, by the light absorbing member of the side member 90.

The side member 90 may be positioned in the gap G formed between the plurality of display modules 30A to 30P, together with the first area 71 of the front cover 70, upon an arrangement of the plurality of display modules 30A to 30P.

Accordingly, by absorbing light entered into the gap G, an amount of light reflected and then emitted to the outside among the light entered the gap G may be minimized. Therefore, visibility of a seam formed by the gap G between the plurality of display modules 30A to 30P may be reduced.

In the example of the first display module 30A and the second display module 30E, the side member 90 of the first display module 30A and the side member 90 of the second display module 30E may be positioned in the gap G formed between the first display module 30A and the second display module 30E, together with the first area 71A of the first front cover 70A and the first area 71E of the second cover 70E.

In the gap G, the side end 95 adjacent to the second display module 30E in the side member 90 of the first display module 30A and the side end 95 adjacent to the first display module 30A in the side member 90 of the second display module 30E may be positioned together with the neighboring side ends 75A and 75E of the front covers 70A and 70E of the first and second display modules 30A and 30E.

The neighboring side ends 75A and 75E of the first and second front covers 70A and 70E may be in contact with each other while facing each other, and the side end 95 adjacent to the second display module 30E in the side member 90 of the first display module 30A and the side end 95 adjacent to the first display module 30A in the side member 90 of the second display module 30E may be in contact with each other while facing each other. The neighboring side ends 75A and 75E of the first and second front covers 70A and 70E may be parallel to and in contact with the side end 95 adjacent to the second display module 30E in the side member 90 of the first display module 30A and the side end 95 adjacent to the first display module 30A in the side member 90 of the second display module 30E.

In the gap G formed between the first display module 30A and the second display module 30E, the neighboring side ends 75A and 75E of the first and second front covers 70A and 70E may be positioned in parallel to the side end 95 adjacent to the second display module 30E in the side member 90 of the first display module 30A and the side end 95 adjacent to the first display module 30A in the side member 90 of the second display module 30E.

As described above, external light entered into the display panel 20 may be diffused and reflected to the outside of the display panel 20 by being transmitted through the first areas 71A and 71E of the first and second front covers 70A and 70E, or a part of the external light may be absorbed in the first areas 71A and 71E of the first and second front covers 70A and 70E. Accordingly, an amount of light arrived at the gap G may be reduced.

In addition, a part of light arrived at the gap G may be absorbed in the side member 90 of the first display module 30A and the side member 90 of the second display module 30A, positioned in the gap G, and accordingly, visibility of a boundary between the first display module 30A and the second display module 30E may be reduced.

That is, by reducing an amount of external light entering the gap G formed between the plurality of display modules 30A to 30P and additionally absorbing light arrived at the gap G, a sense of unity of a screen displayed on the display panel 20 may be improved.

In addition, light reflected from the side member 90 without being absorbed in the side member 90 of each of the first and second display modules 30A and 30E and then traveling to the outside of the display panel 20 may be diffused and reflected to the outside of the display panel 20 by being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, and thus, visibility of the boundary between the first display module 30A and the second display module 30E, caused by the gap G, may be reduced.

Because the side member 90 is positioned in the gap G formed between the plurality of display modules 30A to 30P upon an arrangement of the plurality of display modules 30A to 30P, as described above, the side member 90 may absorb light arrived at the gap G to reduce visibility of a seam, caused by the gap G.

In the above-described example, the front cover 70 may diffuse and reflect, absorb, or circularly polarize a part of light entered the display panel 20, or change a reflection direction of the part of the light, thereby reducing an amount of light that arrives at the substrate 40, although not limited thereto.

However, the front cover 70 may be formed of a transparent material to transmit light without any deformation. In this case, visibility of the boundary between the plurality of display modules 30A to 30P, caused by the gap G, may be reduced by the side member 90 positioned between the plurality of display modules 30A to 30P.

Because the side member 90 is formed of a light absorbing material, as described above, a part of light emitted from the plurality of inorganic light-emitting devices 50 may be absorbed in the side member 90 in a case in which at least one portion of the side member 90 is positioned before the front cover 70 in the first direction X. Accordingly, a part of a screen displayed on the display panel 20 may appear dark.

However, because the side member 90 according to an embodiment of the disclosure is positioned below the front cover 70 in the first direction X, more specifically, below the lower surface of the first area 71, the side member 90 may not absorb light emitted from the plurality of inorganic light-emitting devices 50, and accordingly, brightness of an image displayed on the display panel 20 may be uniform.

As shown in FIGS. 8 and 9, the front cover 70 may extend to the outer location from the substrate 40 in the third direction Z. The front cover 70 may extend to the outer location from the side surface 45 and the chamfer portion 49 in the third direction Z.

The side end 75 of the front cover 70 in the third direction Z may be positioned at a more outer location than the edge 41S of the mounting surface 41 in the third direction Z, or in the gap G.

The first area 71 and the second area 72 of the front cover 70 may be partitioned by the gap G in the third direction Z.

In an example of the first display modules 30A and the third display module 30B, the first area 71A of the first front cover 70A extending from the first display module 30A may be positioned in a gap G formed between the first display module 30A and the third display module 30B.

In the gap G, neighboring side ends 75A and 75B of the front covers 70A and 70B of the first and third display modules 30A and 30B may be positioned.

Also, the side surfaces 45 and chamfer portions 49 of the first and third display modules 30A and 30B may be positioned in the gap G.

A first area 71B of a third front cover 70B extending from the third display module 30B may be positioned in the gap G formed between the first display module 30A and the third display module 30B, and a second area 72B of the third front cover 70B may be positioned above the mounting surface 41 of the third display module 30B.

That is, in the gap G formed between the first display module 30A and the third display module 30B, the first areas 71A and 71B of the first and third front covers 70A and 70B may be positioned side by side in the third direction Z.

External light entered into the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced, and visibility of a boundary between the first display module 30A and the third display module 30B, caused by the gap G, may be reduced.

Also, light reflected in the gap G and then traveling to the outside of the display panel 20 may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the third display module 30B, caused by the gap G, may be reduced.

As described above, the side member 90 may be positioned in a space formed in the side surface 45 of the substrate 40 in the second direction Y and the third direction Z.

On the side surface 45 of the substrate 40 extending in the third direction Z, the side wiring 46 may be positioned.

The side wiring 46 may include a coating member 46a for protecting the side wiring 46 from the outside. The coating member 46a may be applied or coated on the side wiring 46 to prevent the side wiring 46 from being exposed to the outside.

The side portion 120 of the metal cover 100, as shown in the third direction Z, may extend by a preset length from the rear portion 110 in the first direction X. Accordingly, the front end 121 of the side portion 120 may be positioned on the side wiring 46 in the first direction X on the coating member 46a of the side wiring 46.

That is, an area of the side wiring 46 corresponding to the first area 45a of the side surface 45 in the first direction X may be covered by the metal cover 100 to be protected from an external force.

The area of the side wiring 46 corresponding to the first area 45a of the side surface 45 in the first direction X may be adhered to the rear adhesive layer 101 of the metal cover 100.

Another area of the side wiring 46 corresponding to the second area 45b of the side surface 45 in the first direction X may be protected from an external force by the side member 90 surrounding the side wiring 46 in the third direction Z.

The rear surface 43 and the rear wiring layer 43b formed on the rear surface 43, as well as the first area 45a of the side surface 45, may also be protected from an external force by the metal cover 100.

The metal cover 100 may protect the substrate 40 from an external force, and prevent components mounted on the substrate 40 from being damaged by an electrostatic discharge, which will be described below.

Accordingly, the side member 90 and the side portion 120 provided on the side surface 45 positioned toward the third direction Z may surround the side wiring 46, as well as the side surface 45 and the chamfer portion 49. Accordingly, the side wiring 46 may be protected from an external force, and foreign materials or water may be prevented from permeating into the side wiring 46.

That is, because the side member 90 and the side portion 120 surround the lower surface of the first area 71 and the side surface 45 corresponding to each of the four edges 41S of the mounting surface 41 along the four edges 41S of the mounting surface 41, the side member 90 and the side portion 120 may surround the side wiring 46 extending along the side surface 45 in the third direction Z.

Accordingly, adhesion between the front cover 70, the substrate 40, and the metal cover 100 may be improved, and the front cover 70, the side surface 45 of the substrate 40, and the side wiring 46 may be protected from an external force.

The side end 75 of the front cover 70 in the third direction Z and the side end 95 of the side member 90 in the third direction Z may be aligned in the first direction X. The side end 75 of the front cover 70 and the side end 95 of the side member 90 may be aligned in a direction that is in parallel to the first direction X.

Also, the side end 75 of the front cover 70, the side end 47S of the anisotropic conductive layer 47, and the side end 95 of the side member 90 in the third direction Z may be aligned in the first direction X.

In the example of the first display module 30A and the third display module 30B, the side member 90 of the first display module 30A and the side member 90 of the third display module 30B may be positioned in the gap G formed between the first display module 30A and the third display module 30B, together with the first area 71A of the first front cover 70A and the first area 71B of the third front cover 70B.

In the gap G, the neighboring side ends 95 of the side members 90 of the first and third display modules 30A and 30B may be positioned together with the neighboring side ends 75A and 75B of the front covers 70A and 70B of the first and third display modules 30A and 30B.

The neighboring side ends 75A and 75B of the front covers 70A and 70B may be in contact with the neighboring side ends 95 of the side members 90 while facing the neighboring side ends 95 of the side members 90.

The neighboring side ends 75A and 75B of the front covers 70A and 70B may be in contact with the neighboring side ends 95 of the side members 90 while being in parallel to the neighboring side ends 95 of the side members 90.

That is, in the gap G formed between the first display module 30A and the third display module 30B, the first areas 71A and 71B of the first and third front covers 70A and 70B may be positioned in parallel to the side members 90 of the first and third display modules 30A and 30B in the third direction Z.

Because the side end 75 of the front cover 70 and the side end 91 of the side member 90 in the third direction Z are aligned in the first direction X, a space that may be formed between the first and third display modules 30A and 30B upon an arrangement of the first and third display modules 30A and 30B may be minimized.

In the gap G formed between the first display module 30A and the third display module 30B, the first areas 71A and 71B of the first and third front covers 70A and 70B may be arranged in parallel to the side members 90 of the first and third display modules 30A and 30B in the third direction Z.

In the gap G formed between the first display module 30A and the third display module 30B, the first area 71A of the first front cover 70A and the first area 71B of the third front cover 70B may be arranged, and the side members 90 of the first and third display modules 30A and 30B may be arranged behind the first areas 71A and 71B in the first direction X.

As described above, external light entered into the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced.

In addition, light arrived at the gap G may be absorbed in the side members 90 of the first and third display modules 30A and 30B, positioned in the gap G, and accordingly, visibility of the boundary between the first display module 30A and the third display module 30B may be reduced.

Light reflected from the side members 90 and then traveling to the outside of the display panel 20 without being absorbed in the side members 90 may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the third display module 30B, caused by the gap G, may be reduced.

The side member 90 may be applied by a preset amount through a dispenser in a manufacturing process. The applied side member 90 may be hardened through a subsequent process. The side member 90 may be formed of, for example, a nonconductive black resin.

Also, an area of the anisotropic conductive layer 47 positioned outside the mounting surface 41 and the side end 47S of the anisotropic conductive layer 47 may be covered by the applied side member 90.

A process of dispensing the side member 90 may be performed on all of the four edges E of the substrate 40. Accordingly, the side member 90 may be dispensed to cover the entire second area 45b of the side surface 45 of the substrate 40. Also, the entire area of the anisotropic conductive layer 47 positioned outside the mounting surface 41 may be covered by the side member 90.

While the side member 90 is hardened, the side member 90 may be adhered to the lower surface of the front cover 70 in the first direction X, the side surface 45 of the substrate 40, the chamfer portion 49 formed between the side surface 45 and the mounting surface 41, and the area of the anisotropic conductive layer 47 positioned outside the mounting surface 41.

The side member 90 may include a photosensitive material. In this case, by irradiating UV light, etc. to the side member 90 in a subsequent process, the side member 90 may be colored with a dark color. However, the side member 90 may be formed of a translucent or opaque material without including any photosensitive material. In this case, the process may not be required.

The front cover 70 may be formed of a nonconductive material through which no charges are transmitted.

The side member 90 may be formed of a nonconductive material through which no charges are transmitted.

Because the front cover 70 and the side member 90 are formed of a nonconductive material, a major part of current applied to the front cover 70 or the side member 90 may flow on the front cover 70 and the side member 90 without being transmitted through the front cover 70 and the side member 90.

Also, the metal cover 100 may be formed of a material having great capacitance, and function as a ground. Accordingly, upon applying of current to the metal cover 100, the metal cover 100 may be maintained at a constant potential, the current flowing to the metal cover 100 may be absorbed in the metal cover 100, and no current may flow to the substrate 40 through the metal cover 100.

That is, in the display device 1, the entire side wiring 46 of the substrate 40 may be surrounded by the side member 90 and the metal cover 100, and accordingly, the side wiring 46 may be sealed not to be exposed to the outside. Accordingly, static electricity discharged from the side surface 45 of the substrate 40 may not enter the side wiring 46 due to the side member 90 and the metal cover 100.

In a display device manufacturing process of implementing a display panel with display modules, the display panel may be formed by tiling a plurality of display modules. During the process for forming the display panel with the display modules, current generated by an electrostatic discharge may enter the inside of the display modules while the display modules are manufactured and conveyed, which may damage electronic components mounted inside the display modules.

Due to a failure generated during a process of manufacturing the display module 30, a space may be made between the side wiring 46 extending along the side surface of the substrate or the anisotropic conductive layer 47 and the substrate 40 or components mounted on the substrate 40, and the space may be exposed to the outside. During a process of applying the side member 90 and hardening the side member 90, a space may be made inside the side member 90. In this case, according to an electrostatic discharge, current may enter the anisotropic conductive layer 47 or the side wiring 46 and the components mounted on the mounting surface 41 through the space made due to the failure to damage electronic components arranged on the substrate.

The display module 30 may include the front cover 70, the side member 90, and the metal cover 100 for absorbing an electrical shock to prevent current generated by an electrostatic discharge from entering the display module 30 and thus damaging electronic components installed in the display module 30 in a process before being coupled to the frame 15 and assembled into the display device 1.

Accordingly, each of the display modules 30A to 30P may include a component configured to prevent current generated by an electrostatic discharge from entering the components mounted on the substrate 40, and accordingly, current generated by an electrostatic discharge may be easily guided to the metal cover 100 which is a ground component along the front cover 70 and the side member 90 sealing the substrate 40 on each of the display modules 30A to 30P, without entering the components mounted on the substrate 40.

However, due to a failure generated during the process of manufacturing the display modules 30A to 30P, the electronic components may be damaged, as described above. Through a process of covering the substrate 40 with the metal cover 100 after wirings, etc. are mounted on the substrate 40 in the process of manufacturing the display modules 30A to 30P, reliability against ESD may be raised by the metal cover 100 even during a process of manufacturing the substrate 40, which will be described below.

Also, as described above, the metal cover 100 may physically cover the rear surface 43 and the side surface 45 of the substrate 40 and the side wiring 46 to thereby prevent the wirings formed on the rear surface 43 of the substrate 40 and the side wiring 46 from being damaged by an external force while the substrate 40 is manufactured or conveyed.

That is, a process of covering the substrate 40 with the metal cover 100 may be included as one of priority processes in a process sequence of manufacturing the substrate 40, and accordingly, the substrate 40 may be prevented from being damaged by a physical or electrical factor.

Typically, to prevent damage to the substrate 40 such as scratches caused by an external force applied to the substrate 40 in a process of the display modules 30A to 30P, the substrate 40 has been processed after a protective film is adhered to the substrate 40, and accordingly, a process of removing the protective film while processing the substrate 40 has been essentially performed. However, according to an embodiment of the disclosure, because the metal cover 100 covers the substrate 40 in an initial process, an additional process of adhering a protective film to the substrate 40 may not be required.

Also, typically, after the rigidity of the substrate 40 is secured, a metal plate has been attached to the rear surface 43 of the substrate 40 to dissipate heat during driving of the display modules 30A to 30P. However, according to an embodiment of the disclosure, because the metal cover 100 covers the rear surface 43 and at least one portion of the side surface 45, the rigidity of the substrate 40 may be secured without installing an additional metal plate on the substrate 40, and while the display modules 30A to 30P are driven, efficient heat dissipation may be possible through the metal cover 100.

Also, typically, a metal grounding member grounded to the metal plate has been positioned on the side surface 45 of the substrate 40 to secure reliability against ESD of the display modules 30A to 30P, which requires an additional process and increases a space between the display modules 30A to 30P. However, according to an embodiment of the disclosure, because reliability against ESD of the display modules 30A to 30P is secured through the metal cover 100, reliability against ESD of the substrate 40 may be secured without a metal plate and a grounding member.

Hereinafter, a method of manufacturing the display module 30 according to an embodiment of the disclosure will be described in detail,

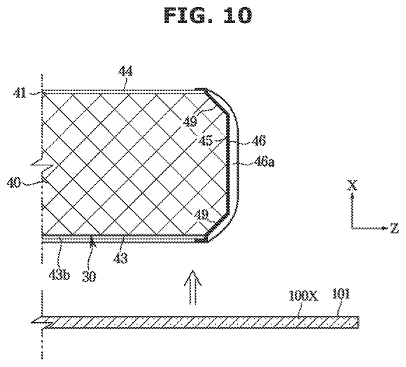

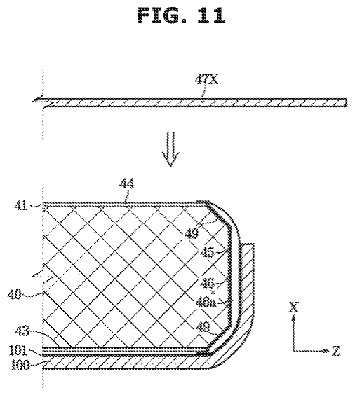

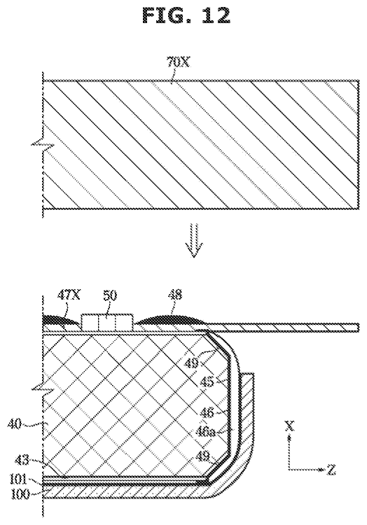

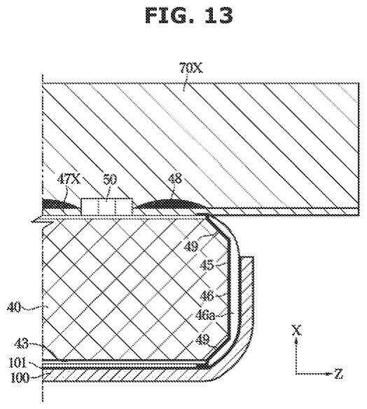

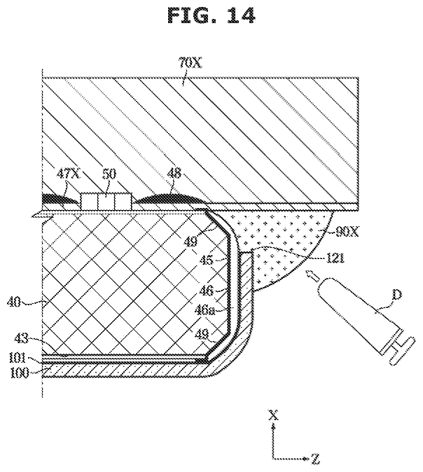

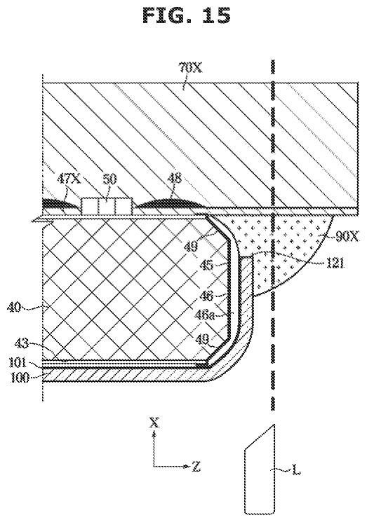

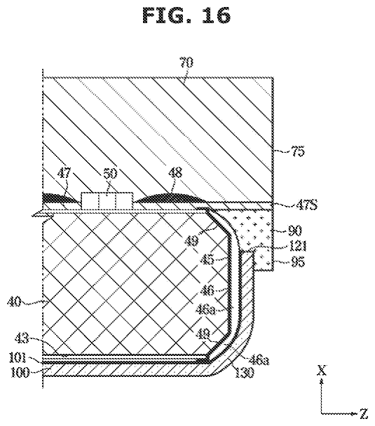

FIG. 10 shows a process of manufacturing a display device according to an embodiment of the disclosure, FIG. 11 shows a process of manufacturing the display device after FIG. 10, FIG. 12 shows a process of manufacturing the display device after FIG. 11, FIG. 13 shows a process of manufacturing the display device after FIG. 12, FIG. 14 shows a process of manufacturing the display device after FIG. 13, FIG. 15 shows a process of manufacturing the display device after FIG. 14, and FIG. 16 shows a process of manufacturing the display device after FIG. 15.

First, as shown in FIG. 10, the substrate 40 in which the TFT layer 44, the rear wiring layer 43b, and the side wiring 46, etc. are formed on the mounting surface 41 may be prepared, and a metal cover 100X being in a shape of a sheet may be adhered to the rear surface 43 of the substrate 40 to cover the substrate 40.

The rear adhesive layer 101 may be positioned on a side of the metal cover 100X toward the rear surface 43 to adhere the metal cover 100X to the substrate 40.

The metal cover 100X may be provided substantially in a shape of a rectangular sheet, and after the metal cover 100X is adhered to the rear surface 43, the metal cover 100X may be bent in a direction toward the side surface 45 to cover at least one portion of the side surface 45 and the side wiring 46.

Thereafter, as shown in FIG. 11, the metal cover 100 may be bent to cover the rear surface 43, at least one portion of the side surface 45, and at least one portion of the side wiring 46. Because the metal cover 100 covers the substrate 40, the substrate 40 may be prevented from being damaged by an external force in subsequent processes.

An anisotropic conductive film 47X may be adhered onto the TFT layer 44 of the substrate 40 covered with the metal cover 100.

The anisotropic conductive film 47X may extend to a more outer location than the side wiring 46 with respect to the side surface 45 in the third direction Z.

The anisotropic conductive film 47X may be formed in a shape of a film, and an area of the anisotropic conductive film 47X may be larger than an area of the substrate 40. Accordingly, after the anisotropic conductive film 47X is adhered to the TFT layer 44, a process of cutting the anisotropic conductive film 47X to correspond the area of the anisotropic conductive film 47X to the area of the substrate 40 may be performed. The cutting process may be laser cutting, etc., and in a subsequent process, the anisotropic conductive film 47X may be cut together with a front cover 70X and a side member 90X, although not limited thereto. However, the anisotropic conductive film 47 may be cut before the front cover 70X and the side member 90X are cut.

The anisotropic conductive film 47X may be in a state before being cut to form the anisotropic conductive layer 47.

Then, the plurality of inorganic light-emitting devices 50 may be mounted on the mounting surface 41 and electrically connected to the wiring of the substrate 40 by the anisotropic conductive film 47X.

Thereafter, as shown in FIG. 12, the front cover 70X may be adhered on the mounting surface 41 of the display module 30 on which the plurality of inorganic light-emitting devices 50 and the electronic components constituting the display module 30 are mounted.

By positioning the front cover 70X on the anisotropic conductive film 47X, the front cover 70X may be adhered to the mounting surface 41 to cover the mounting surface 41. The front cover 70X may be in a state before being cut. The front cover 70X may cover an entire area of the mounting surface 41.

Then, the front cover 70X may be, as shown in FIG. 13, adhered on the mounting surface 41 through a compression hardening process on the mounting surface 41.

Then, as shown in FIG. 14, the side member 90X may be dispensed in a space between the chamfer portions 49 formed between the lower surface of the anisotropic conductive film 47X in the first direction X and the side surfaces 45 of the substrate 40.

The side member 90X may be the side member 90X before being cut together with the front cover 70X.

The side member 90X may be applied by a preset amount through a dispenser D. The applied side member 90X may be hardened through a subsequent process. The side member 90X may be formed of, for example, a nonconductive black resin.

The side member 90X may be applied to cover all the lower surface of the anisotropic conductive film 47X, at least one portion of the side surface 45 of the substrate 40, the chamfer portion 49 formed between the mounting surface 41 and the side surface 45, at least one portion of the side wiring 46 in the third direction Z, and at least one portion of the metal cover 100 covering at least one portion of the side surface 45 and the side wiring 46.

The side member 90X may be applied such that the front end 121 of the side portion 120 of the metal cover 100 is positioned inside the side member 90X.

A process of dispensing the side member 90X may be performed on all of the four edges E of the substrate 40. Accordingly, the side member 90X may be dispensed to cover all of the edges E of the substrate 40. An entire area 47X of the anisotropic conductive layer 47, positioned outside the mounting surface 41, may be covered by the side member 90X.

While the side member 90X is hardened, the lower surface of the anisotropic conductive film 47 in the first direction, the at least one portion of the side surface 45 of the substrate 40, the chamfer portion 49 formed between the side surface 45 and the mounting surface 41, the at least one portion of the side wiring 46, and the at least one portion of the metal cover 100 may be adhered to the side member 90X.

The side member 90X may include a photosensitive material. In this case, by irradiating UV light or the like, as a subsequent operation, the side member 90X may be colored with a dark color. However, the side member 90X may be formed of a translucent or opaque material without including any photosensitive material. In this case, the process may not be required.

Then, as shown in FIG. 15, the front cover 70X, the anisotropic conductive film 47X, and the side member 90X may be cut in the first direction X such that at least one portion of the front cover 70X extends to an outer location from the substrate 40 in the second and third directions Y and Z that are orthogonal to the first direction X which the mounting surface 41 faces.

The cutting process may be performed by laser (L) cutting or the like. Accordingly, the front cover 70X, the side member 90X, and the anisotropic conductive film 47X may be cut simultaneously.

Then, as shown in FIG. 16, after the cutting terminates, the side end 75 of the front cover 70, the side end 47S of the anisotropic conductive layer 47, and the side end 95 of the side member 90 may be aligned in the first direction X.

A display device according to an embodiment of the disclosure may have a seamless effect in which seams are not visible by absorbing light entering gaps between neighboring display modules.

A display device according to an embodiment of the disclosure may secure reliability against Electrostatic Discharge (ESD) of a substrate of each display module and rigidity against an external force of the substrate by a metal cover covering a rear surface and side surfaces of the substrate.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

1. A display module comprising:
a substrate comprising a mounting surface on which a plurality of inorganic light-emitting devices are mounted, a side surface, and a rear surface opposite to the mounting surface;
a front cover covering the mounting surface and extending to an outer area from the mounting surface;
a metal cover covering the rear surface and a first area of the side surface, the first area extending from the rear surface; and
a side member positioned below the outer area from the mounting surface and adhered to a second area of the side surface, the second area extending from the mounting surface, and at least a portion of the metal cover.

2. The display module of claim 1, wherein the metal cover comprises a rear portion covering the rear surface, a side portion covering the first area of the side surface, and a bent portion bent between the rear portion and the side portion.

3. The display module of claim 2, wherein the rear portion, the side portion, and the bent portion are integrated into one body.

4. The display module of claim 1, further comprising a Thin Film Transistor (TFT) layer formed on the mounting surface, and an anisotropic conductive layer positioned on an upper surface of the TFT layer and configured to electrically connect the TFT layer to the plurality of inorganic light-emitting devices,
wherein the anisotropic conductive layer extends to the outer area from the mounting surface.

5. The display module of claim 4, wherein the front cover comprises a side end positioned in the outer area from the mounting surface,
wherein the anisotropic conductive layer comprises a side end positioned in the outer area from the mounting surface, and
wherein the side end of the front cover and the side end of the anisotropic conductive layer are aligned in a direction which the mounting surface faces.

6. The display module of claim 4, wherein the side member is adhered to at least a portion of a lower surface of the anisotropic conductive layer, the at least a portion of the lower surface corresponding to the outer area from the mounting surface.

7. The display module of claim 6, wherein the side member comprises a side end positioned at an outer location from the side surface, and
wherein the side end of the side member, the side end of the front cover, and the side end of the anisotropic conductive layer are aligned in the direction which the mounting surface faces.

8. The display module of claim 1, wherein the side member comprises a lower end forming a lower surface of the side member, and
wherein the lower end of the side member is positioned below the second area of the side surface in a direction which the mounting surface faces.

9. The display module of claim 1, wherein the substrate further comprises a side wiring extending from the mounting surface to the rear surface and configured to electrically connect to the plurality of inorganic light-emitting devices, and
wherein the metal cover covers at least a portion of the side wiring extending on the side surface from the rear surface.

10. The display module of claim 9, wherein the side member covers at least a portion of the side wiring extending on the side surface from the mounting surface.

11. The display module of claim 1, wherein the metal cover comprises a conductivity greater than a conductivity of the front cover and a conductivity of the side member.

12. The display module of claim 1, wherein the side member comprises a light absorbing material.

13. A display device comprising a display module array in which a plurality of display modules are arranged horizontally in a matrix form of M*N, wherein each of the plurality of display modules comprises:
a substrate comprising a mounting surface on which a plurality of inorganic light-emitting devices are mounted, a side surface, and a rear surface opposite to the mounting surface;
a front cover covering the mounting surface and extending to an outer area from the mounting surface;
a metal cover covering the rear surface and a first area of the side surface, the first area extending from the rear surface; and
a side member positioned below the outer area from the mounting surface and adhered to a second area of the side surface, the second area extending from the mounting surface, and
at least a portion of the metal cover.

14. The display device of claim 13, wherein the metal cover comprises a rear portion covering the rear surface, a side portion covering the first area of the side surface, and a bent portion bent between the rear portion and the side portion.

15. The display device of claim 13, further comprising a Thin Film Transistor (TFT) layer formed on the mounting surface, and an anisotropic conductive layer positioned on an upper surface of the TFT layer and configured to electrically connect the TFT layer to the plurality of inorganic light-emitting devices,
wherein the anisotropic conductive layer extends to the outer area from the mounting surface.
